(19) United States
(12) Patent Application Publication
(10) Pub. No.: US 2025/0218789 A1
(43) Pub. Date: Jul. 3, 2025

(54) SUBSTRATE PROCESSING METHOD

(71) Applicant: TES Co., Ltd, Yongin-si (KR)

(72) Inventors: Bongsoo KWON, Yongin-si (KR); Sewoong Bae, Yongin-si (KR); Donggeun Choi, Yongin-si (KR)

(73) Assignee: TES Co., Ltd, Yongin-si (KR)

(21) Appl. No.: 19/002,777

(22) Filed: Dec. 27, 2024

(30) Foreign Application Priority Data
Dec. 27, 2023 (KR) 10-2023-0193301
Dec. 11, 2024 (KR) 10-2024-0184105

(51) Int. Cl. H01L 21/311

(52) U.S. Cl. CPC H01L 21/31116

(57) ABSTRACT

Disclosed is a substrate processing method which may easily adjust an etching profile in a thickness direction of a substrate. In the method, the substrate has an ONO stack formed thereon, wherein the ONO stack includes a stack structure in which silicon oxide layers and silicon nitride layers are alternately stacked on top of each other, wherein a through-hole extends through the ONO stack such that side surfaces of the silicon oxide layers and the silicon nitride layers are exposed. The method includes: (a) supplying a first processing gas to the through-hole to expose the ONO stack to the first processing gas; and (b) supplying a second processing gas to the through-hole to expose the ONO stack to the second processing gas to dry-etch the silicon nitride layers of the ONO stack, wherein the first processing gas includes CₓF_{y}, wherein a x/y is 0.5 or greater.

### CROSS-REFERENCE TO RELATED APPLICATIONS

This application claims priority to Korean Patent Application Nos. 10-2023-0193301 (filed on Dec. 27, 2023) and 10-2024-0184105 (filed on Dec. 11, 2024), which are all hereby incorporated by reference in their entirety.

### BACKGROUND

The present disclosure relates to a method for processing a substrate including an oxide-nitride-oxide (ONO) stack in which silicon oxide layers and silicon nitride layers are alternately stacked on top of each other. More specifically, the present disclosure relates to a method of selectively dry-etching the nitride layers in the ONO stack.

When manufacturing a semiconductor device, an ONO stack in which the silicon oxide layers and the silicon nitride layers are alternately stacked on top of each other may be formed on a substrate. In order to selectively etch the silicon nitride layers in the ONO stack, an etchant having a higher etch selectivity than that of the silicon oxide layer should be applied.

In order to selectively etch the silicon nitride layer in the dry-etching process, carbon tetrafluoride (CF₄), nitrogen trifluoride (NF₃), and the like are mainly used as etching gases. In this regard, hydrogen-containing etching gases such as monofluoromethane (CH₃F) or difluoromethane (CH₂F₂) were not well used in the dry-etching of silicon nitride, because a thick polymer film was generated due to hydrogen radicals when the etching gas was converted to the plasma. Such a thick polymer layer reduces an etch rate of the silicon nitride layer.

On the other hand, recently, the number of layers of the ONO stack is increasing to 200 to 300 layers. In this case, in the dry-etching process, the silicon nitride layers adjacent to the surface (i.e., the nitride layers constituting the upper portion of the ONO stack) are rapidly etched, whereas the silicon nitride layers adjacent to the substrate (i.e., the nitride layers constituting the lower portion of the ONO stack) are less efficiently etched. In general, it is not easy to selectively etch only the nitride layer constituting the lower portion of the ONO stack. When the nitride layers constituting the upper portion of the ONO stack have already been etched, it is more difficult to selectively etch only the nitride layer constituting the lower portion of the ONO stack. That is, when the nitride layers constituting the upper portion of the ONO stack are first etched, it is difficult to control the etch profile in the thickness direction of the substrate.

In addition, during the selective dry-etching of the silicon nitride layer, a portion of the silicon oxide layer is lost or the thickness of the silicon oxide layer becomes smaller, and thus, the silicon oxide layer is damaged, or a regrowth oxide is generated in the damaged silicon oxide layer.

### SUMMARY

A purpose of the present disclosure is to provide a substrate processing method in which an etching profile in a substrate thickness direction of an ONO stack is easily adjusted.

In addition, a purpose to be achieved by the present disclosure is to provide a substrate processing method capable of increasing the etching rate of the lower portion of the ONO stack while suppressing the etching of the silicon oxide layers and the silicon nitride layers constituting the upper portion of the ONO stack.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

In order to achieve the purposes, a first aspect of the present disclosure provides a method for processing a substrate having an ONO stack formed thereon, wherein the ONO stack includes a stack structure in which silicon oxide layers and silicon nitride layers are alternately stacked on top of each other, wherein a through-hole extends through the ONO stack such that side surfaces of the silicon oxide layers and the silicon nitride layers are exposed, the method comprising: (a) supplying a first processing gas to the through-hole to expose the ONO stack to the first processing gas; and (b) supplying a second processing gas to the through-hole to expose the ONO stack to the second processing gas to dry-etch the silicon nitride layers of the ONO stack, wherein the first processing gas includes CₓF_{y}, wherein a x/y is 0.5 or greater.

In accordance with some embodiments of the method of the first aspect, in the (a), a carbon-containing film is formed on exposed side surfaces of the silicon oxide layers and the silicon nitrides of an upper portion of the ONO stack.

In accordance with some embodiments of the method of the first aspect, the first processing gas includes C₄F₆ or C₄F₈.

In accordance with some embodiments of the method of the first aspect, in the (a), the ONO stack is exposed to plasma into which the first processing gas has been converted.

In accordance with some embodiments of the method of the first aspect, the second

processing gas includes a fluorine-containing gas except for nitrogen trifluoride (NF₃) and a hydrogen-containing gas.

In accordance with some embodiments of the method of the first aspect, an atomic ratio (F:H) of fluorine and hydrogen contained in the second processing gas is in a range of 15:1 to 35:1.

In accordance with some embodiments of the method of the first aspect, in the (b), the ONO stack is exposed to plasma into which the second processing gas has been converted.

In accordance with some embodiments of the method of the first aspect, high frequency power having an RF frequency of 15 MHz inclusive to 60 MHz exclusive is used for converting the second processing gas into the plasma.

A second aspect of the present disclosure provides a method for processing a substrate having an ONO stack formed thereon, wherein the ONO stack includes a stack structure in which silicon oxide layers and silicon nitride layers are alternately stacked on top of each other, wherein a through-hole extends through the ONO stack such that side surfaces of the silicon oxide layers and the silicon nitride layers are exposed, the method comprising: (a) placing the substrate in a reaction chamber; (b) supplying a first processing gas into the reaction chamber; (c) purging an inside of the reaction chamber using a purge gas; (d) supplying a second processing gas into the reaction chamber; (e) purging the inside of the reaction chamber using a purge gas; and (f) performing a unit cycle a plurality of times, wherein (b) to (e) constitute the unit cycle, wherein the first processing gas includes CₓF_{y}, wherein a x/y is 0.5 or greater, wherein the second processing gas is an etching gas.

In accordance with some embodiments of the method of the second aspect, in the (b), a carbon-containing film is formed on exposed side surfaces of the silicon oxide layers and the silicon nitrides of an upper portion of the ONO stack.

In accordance with some embodiments of the method of the second aspect, the first processing gas includes C₄F₆ or C₄F₈.

In accordance with some embodiments of the method of the second aspect, in the (b), RF power is applied to the reaction chamber for converting the first processing gas into plasma.

In accordance with some embodiments of the method of the second aspect, the second processing gas includes a fluorine-containing gas except for nitrogen trifluoride (NF₃) and a hydrogen-containing gas.

In accordance with some embodiments of the method of the second aspect, an atomic ratio (F:H) of fluorine and hydrogen contained in the second processing gas is in a range of 15:1 to 35:1.

In accordance with some embodiments of the method of the second aspect, in the (d), RF power is applied to the reaction chamber for converting the second processing gas into plasma.

In accordance with some embodiments of the method of the second aspect, the RF power has a RF frequency of 15 MHz inclusive to 60 MHz exclusive.

In accordance with some embodiments of the method of the second aspect, the substrate processing method further comprises (g) supplying a third processing gas into the reaction chamber to further etch the silicon nitride layers of the ONO stack.

In accordance with some embodiments of the method of the second aspect, a type of the third processing gas is identical with a type of the second processing gas.

In the substrate processing method according to the present disclosure, a carbon-containing deposition film constituting the upper portion of the ONO stack is first formed using a carbon rich compound such as C₄F₆ and then dry-etching is performed. The carbon-containing deposition layer may serve as an etch stop film against the etching gas, so that the etching of the lower portion of the ONO stack may be performed while the etching of the upper portion of the ONO stack is stopped. Since the lower portion of the ONO stack is first etched, the etching profile in the thickness direction of the substrate may be easily adjusted.

In the substrate processing method according to the present disclosure, using the carbon-rich compound, etching of silicon oxide as well as silicon nitride of the ONO stack may be suppressed, thereby suppressing or reducing the occurrence of the re-growth oxide.

In addition, the substrate processing method according to the present disclosure uses the carbon-rich compound, thereby reducing the amount of by-products produced as compared with the use of the compound having a lower carbon content in the processing process.

The effects of the present disclosure are not limited to the above-mentioned effects, and other effects as not mentioned will be clearly understood by those skilled in the art from the following detailed description.

### BRIEF DESCRIPTION OF DRAWINGS

FIG. 1 schematically shows that the silicon nitride layers of the upper portion (adjacent to the surface) of the ONO stack are mainly etched according to the related art.

FIG. 2 is a flowchart schematically illustrating a substrate processing method according to an embodiment of the present disclosure.

FIG. 3 schematically shows that the silicon nitride layers of the lower portion (adjacent to the substrate) of the ONO stack are mainly etched while the silicon nitride layers and the silicon oxide layers of the upper portion of the ONO stack are protected according to the present disclosure.

FIG. 4 is a flowchart schematically illustrating a substrate processing method according to another embodiment of the present disclosure.

### DETAILED DESCRIPTIONS

Hereinafter, a preferred embodiment of the present disclosure will be described in detail with reference to the accompanying drawings. Advantages and features of the present disclosure, and a method of achieving the advantages and features will become apparent with reference to embodiments described below in detail together with the accompanying drawings. However, the present disclosure is not limited to the embodiments as disclosed below, but may be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Hereinafter, a substrate processing method according to a preferred embodiment of the present disclosure will be described in detail with reference to the accompanying drawings as follows.

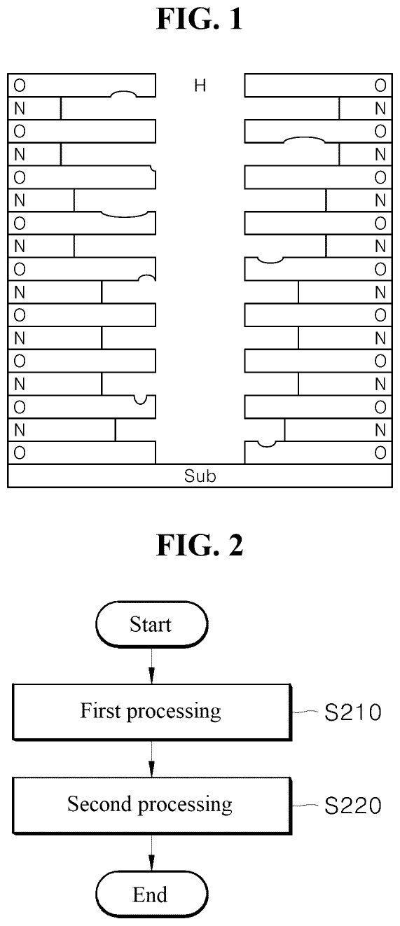

FIG. 1 schematically shows that the silicon nitride layers of the upper portion (adjacent to the surface) of the ONO stack are mainly etched according to the related art.

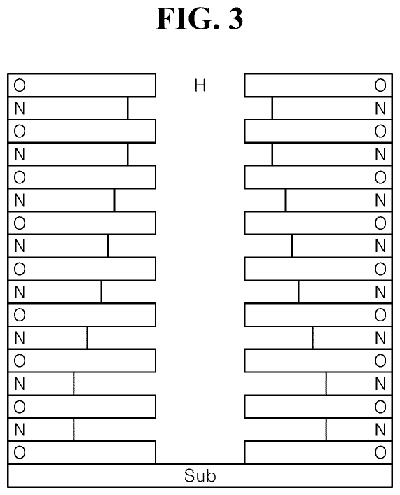

Hereinafter, in FIGS. 1 and 3, reference numeral Sub denotes a substrate, N denotes a silicon nitride layer, O denotes a silicon oxide layer, and H denotes a through-hole.

Referring to FIG. 1, an oxide-nitride-oxide (ONO) stack in which silicon oxide layers O and silicon nitride layers N are alternately stacked on top of each other is formed on the substrate Sub. For example, the ONO stack may have a structure in which the silicon oxide layers and the silicon nitride layers are alternately stacked on top of each other, wherein each of the number of the silicon oxide layers and the number of the silicon nitride layers is several, dozens, or even 200 to 300.

In accordance with the present disclosure, the upper portion of the ONO stack may be a portion up to ⅓ in the downward direction from the surface of the ONO stack, the lower portion of the ONO stack may be a portion up to ⅓ in the upward direction from the substrate contact surface of the ONO stack, and the middle portion of the ONO stack may be a portion between the upper portion and the lower portion.

Referring to FIG. 1, in a conventional dry-etching process, silicon nitride layers adjacent to a surface of the ONO stack (i.e., silicon nitride layers of the upper portion of the ONO stack) are rapidly etched, whereas etching efficiency of the silicon nitride layers adjacent to the substrate (i.e., silicon nitride layers of the lower portion of the ONO stack) of the ONO stack is degraded.

In addition, during the selective dry-etching of the silicon nitride layer, a portion of the silicon oxide layer is lost or the thickness of the silicon oxide layer is reduced, thereby damaging the silicon oxide layer. In addition, there is a problem in that a regrowth oxide is generated in the damaged silicon oxide layer.

FIG. 2 schematically shows a method for processing a substrate according to an embodiment of the present disclosure.

Referring to FIG. 2, the substrate processing method according to an embodiment of the present disclosure includes a first processing step S110 and a second processing step S120.

In the substrate processing method according to the present disclosure, the silicon nitride layers in the ONO stack in which silicon oxide layers and silicon nitride layers are alternately stacked on top of each other on the substrate are selectively treated while at least one through-hole such as a central through-hole is formed in the ONO stack, and thus side surfaces of the silicon oxide layers and the silicon nitride layers are exposed.

First, in the first processing step S210, a first processing gas is supplied to the through-hole TH to expose the ONO stack to the first processing gas.

In accordance with the present disclosure, the first processing step S210 is a step for forming an etch stop film or a protective film on the silicon oxide and the silicon nitride constituting the upper portion of the ONO stack through the through-hole. In accordance with the present disclosure, in a state in which the etch stop film or the protective film has been formed on the silicon oxide layers and the silicon nitride layers constituting the upper portion of the

ONO stack, a second processing gas, that is, an etching gas, which will be described later, is supplied to etch the silicon nitride layers of the lower portion and the middle portion of the ONO stack first.

The first processing gas includes CₓF_{y} and has a x/y of 0.5 or greater. This corresponds to a carbon rich gas in which an atomic content of the carbon is higher than that of the fluorine.

In general, a gas in which an atomic content of the carbon is lower than that of the fluorine, for example, CF₄, corresponds to a gas in which silicon nitride etching is dominant. However, in the case of carbon rich gas having the atomic ratio between the contents of carbon and fluorine is 0.5 or greater, such as C₄F₆ and C₄F₈, deposition of a carbon-containing film is more dominant than silicon nitride etching. The CₓF_{y} as the first processing gas may be supplied alone into the reaction chamber, or may be supplied together with an inert gas as a carrier gas to the reaction chamber.

Through the first processing step S210, a carbon-containing film may be formed on the silicon oxide layers and the silicon nitrides of the upper portion of the ONO stack, and the carbon-containing film may act as an etch stop film or a protective film on the top silicon oxide layers and the silicon nitrides of the ONO stack.

In particular, like the etching gas, the first processing gas is mainly concentrated on the upper portion of the ONO stack, and accordingly, the carbon-containing film is mainly formed on the surface of silicon oxide and silicon nitride constituting the upper portion of the ONO stack. The formation amount of the carbon-containing film decreases as the ONO stack extends downwardly to the substrate, such that the carbon-containing film may be minimally formed on the surface of silicon oxide and silicon nitride of the lower portion of the ONO stack.

In the first processing step S210, the ONO stack may be exposed to the plasmarized first processing gas. That is, the first processing step related to deposition may be performed in the plasma process. The first processing step S210 may be performed under conditions such as RF power of 3000 W or lower such as 700 to 2500 W, a process pressure of 0.3 to 10 Torr, a susceptor surface temperature of 0 to 50° C., and the like. However, the present disclosure is not limited thereto, and various known process conditions may be applied.

Next, in the second processing step S220, a second processing gas is supplied to the through-hole, such that the ONO stack is exposed to the second processing gas to dry-etch the silicon nitrides of the ONO stack.

The second processing gas includes an etching gas for selectively etching the silicon nitride. As the etching gas, an etching gas having a higher selectivity to silicon nitride than silicon oxide, for example, carbon tetrafluoride (CF₄) may be used. In addition, in another example, a CHₓF_{y} gas, such as trifluoromethane (CHF₃), difluoromethane (CH₂F₂), and monofluoromethane (CH₃F), may be used as the etching gas. The fluorine-containing gas may be used alone or in a mixture of two or more thereof. Preferably, CF₄ and CH₂F₂ may be used together. In addition, the etching gas may include a hydrogen-containing gas that does not contain a fluorine component, such as H₂ and NH₃. Therefore, the second processing gas may include a fluorine-containing gas and a hydrogen-containing gas. The second processing gas may be supplied into the reaction chamber alone, or may be supplied together with an inert gas as a carrier gas thereto. However, it is preferable that nitrogen trifluoride (NF₃) does not belong to the second processing gas. In the case of using nitrogen trifluoride (NF₃), the silicon oxide layer as well as the silicon nitride layer is etched to some extent. Thus, it is preferable that the nitrogen trifluoride (NF₃) be excluded from a plurality of gases for selective etching of the silicon nitride layer.

The flow rate of the second processing gas may be set to about 800 sccm or lower in the case of tetrafluoromethane (CF₄), and may be set to about 200 sccm or lower in the case of a fluoromethane-based gas such as difluoromethane (CH₂F₂). However, the present disclosure is not limited thereto.

In one example, the second processing gas may further include nitrogen and/or oxygen. Nitrogen binds to oxygen to form NO to contribute to the silicon nitride layer etching. Oxygen also contributes to the removal of process by-products. Nitrogen may be supplied into the process chamber at a flow rate of, for example, 2000 sccm or lower, and oxygen may be supplied into the process chamber at a flow rate of, for example, 3000 sccm or lower.

In one example, it is more preferable that the atomic ratio (F:H) of fluorine and hydrogen contained in the second processing gas is in a range of 15:1 to 35:1. For example, an atomic ratio (F:H) of fluorine and hydrogen contained in the plurality of gases may be in a range of 15:1 inclusive to 22.5:1 exclusive. In another example, an atomic ratio (F:H) of fluorine and hydrogen contained in the plurality of gases may be in a range of 22.5:1 inclusive to 35:1 inclusive. When the atomic ratio (F:H) of fluorine and hydrogen is smaller than 15:1, hydrogen is excessively present, such that a polymer film generated from plasma is thickly formed on the surfaces of the silicon oxide layer and the silicon nitride layer, and accordingly, the etch rate of the silicon nitride layer may be greatly reduced. On the contrary, when the atomic ratio (F:H) of fluorine and hydrogen exceeds 35:1, the polymer film is formed to be too thin due to a lack of hydrogen, and thus the etch rate of the silicon oxide film is also increased, thereby causing damage to the pattern.

In the second processing step S220, the ONO stack may be exposed to the plasmarized second processing gas. That is, the second processing step S220 may be performed in a plasma etching process. Preferably, a high frequency power having a RF frequency of 15 MHz inclusive to 60 MHz exclusive for the converting of the second processing gas to the plasma may be used. It is more preferable that the RF frequency is in a range of 15 to 50 MHz. When the RF frequency is lower than 15 MHz, such as 13.56 MHz, the plasmatization and decomposition efficiency of the second processing gas is low, and accordingly, it may be difficult for most of etching radicals to reach the lower portion of the ONO stack. On the other hand, when the RF frequency is 60 MHz or higher, such as 60 MHz and 67.8 MHz, it may be difficult to obtain a desired etch profile even through adjustment of other process conditions due to excessive ionization and decomposition efficiency.

In addition, the plasma mode used in accordance with the present disclosure is more preferably a CCP mode among an inductively coupled plasma (ICP) mode or a capacitively coupled plasma (CCP) mode. In the case of the CCP mode, the uniformity is superior to that in the ICP mode such that a more uniform process result of the device may be obtained in the large-sized substrate processing.

The second processing step S220 may be performed under conditions of a RF power of 700 to 2500 W, a process pressure of 0.3 to 10 Torr, a susceptor surface temperature of 0 to 50° C., and the like. However, the present disclosure is not limited thereto, and various known process conditions may be applied.

After the second processing step S220, a heat treatment may be performed to remove the condensation film formed on the surface of the silicon nitride layer during the etching process. The heat treatment may be performed in a temperature range of 80 to 300° C.

FIG. 3 schematically shows that the silicon nitride layers of the lower portion (adjacent to the substrate) of the ONO stack are mainly etched while the silicon nitride layers and the silicon oxide layers of the upper portion of the ONO stack are protected according to the present disclosure.

In accordance with the present disclosure, the carbon-containing film is formed on the silicon oxide layers and the silicon nitride layers of the ONO stack by using a carbon rich gas in which an atomic content of the carbon is higher than that of the fluorine. The carbon-containing film is mainly formed on the silicon oxide layers and the silicon nitride layers constituting the upper portion of the ONO stack. It is believed that this is due to a result that the deposition reaction is mainly performed on the upper portion of the ONO stack, and the deposition reaction is poorly performed on the middle portion and the lower portion of the ONO stack. As a result of exposing the stack to the etching gas such as CF₄ or CHₓF_{y} in a state in which the carbon-containing layer has been formed on the upper portion of the ONO, the silicon nitride layers of the upper portion of the ONO stack are hardly etched, and the silicon nitrides of the middle and lower portion of the ONO stack may be etched as shown in FIG. 3.

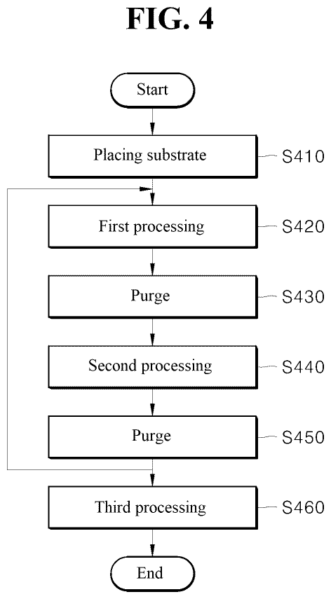

FIG. 4 is a flowchart schematically illustrating a substrate processing method according to another embodiment of the present disclosure.

As in the substrate processing method illustrated in FIG. 2, in the substrate processing method illustrated in FIG. 4, the silicon nitride layers in the ONO stack in which silicon oxide layers and silicon nitride layers are alternately stacked on top of each other on the substrate are selectively treated while at least one through-hole such as a central through-hole is formed in the ONO stack, and thus side surfaces of the silicon oxide layers and the silicon nitride layers are exposed.

The substrate processing method illustrated in FIG. 4 includes a substrate placing step S410, a first processing gas supplying step S420, a purge step S430, a second processing gas supplying step S440, and a purge step S450. When the first processing gas supply step S420, the purge step S430, the second processing gas supply step S440, and the purge step S450 constitute a unit cycle, this unit cycle is performed a plurality of times.

First, in the substrate placing step S410, a substrate to be processed, that is, a substrate on which the ONO stack has been formed, is placed on a susceptor in the reaction chamber.

Next, in the first processing gas supply step S420, the first processing gas is supplied into the reaction chamber. In the first processing gas supply step S420, a carbon-containing film may be formed on the surfaces of the silicon oxide layers and the silicon nitride layers constituting the upper portion of the ONO stack by using a carbon rich gas including CₓF_{y} such as C₄F₆ or C₄F₈ and having a x/y of 0.5 or greater. The carbon-containing film may act as an etch stop film or a protective film in the second processing gas supply step S440 to be described later.

The first processing gas supply step S420 is substantially the same as the first processing step S210 of FIG. 2, and thus a detailed description thereof will be omitted.

Next, in the purge step S430, a purge gas is supplied into the reaction chamber to purge the inside of the reaction chamber. As the purge gas, an inert gas such as nitrogen gas, argon gas, or the like may be used.

Next, in the second processing gas supply step S440, the second processing gas is supplied into the reaction chamber. The second processing gas may include an etching gas for etching the silicon nitride layers of the ONO stack.

The second processing gas supply step S440 is performed in a state in which the etch stop film or the protective film has been formed on the upper portion of the ONO stack through the first processing gas supply step S420 as described above. In this step S440, the silicon nitride layers of the middle portion and the lower portion of the ONO stack are mainly etched.

The second processing gas supply step S440 is substantially the same as the second processing step S220 of FIG. 2, and thus a detailed description thereof will be omitted.

Next, in the purge step S450, a purge gas is supplied into the reaction chamber to purge the inside of the reaction chamber. As the purge gas, an inert gas such as nitrogen gas, argon gas, or the like may be used. In the purge step S450, the same gas as the purge gas used in the aforementioned purge step S430 may be used, but is not necessarily limited thereto.

Meanwhile, in order to improve deposition and etching efficiency, the purge steps S430 and S450 may also be performed during the first processing gas supply step S420 and the second processing gas supply step S440.

In one example, the carbon-containing film formed on the upper portion of the ONO stack may be thinned or peeled away as the etching is performed in the second processing gas supply step S440. In order to suppress this thinning or peel-away as much as possible, the method may include a step of performing the unit cycle a plurality of times, wherein the first processing gas supply step S420, the purge step S430, the second processing gas supply step S430, and the second processing gas supply step S440 constitute the unit cycle. Thus, the etching of the silicon nitride layers of the middle and lower portions of the ONO stack in the second processing gas supply step S430 may be performed in a state in which the etch stop film or the protective film has been stably formed on the upper portion of the ONO stack.

After the sufficient etching of the silicon nitride layers of the middle and lower portions of the ONO stack is performed through the above processes, a third processing gas may be supplied into the reaction chamber to further etch the silicon nitride layer of the ONO stack (S460). In the step S460, for example, as shown in FIG. 1, the silicon nitride layers constituting the upper portion of the ONO stack may be mainly etched.

Before the third processing gas is supplied, the carbon-containing film formed on the upper portion of the ONO stack may be removed by an etching process using phosphoric acid.

The third processing gas may be the same type of gas as that of the second processing gas.

As described above, in the substrate processing method according to the present disclosure, deposition is first performed using the C (carbon) rich gas, and then dry-etching is performed, thereby obtaining an etching profile in which etching of the upper portion of the substrate is suppressed and etching of the middle and lower portions of the substrate is performed. Thereafter, the etching profile in the thickness direction of the substrate may be easily adjusted through a subsequent etching process.

In addition, in the substrate processing method according to the present disclosure, using the carbon-rich compound, not only the silicon nitride of the ONO stack but also the etching of the silicon oxide thereof may be suppressed, thereby suppressing or reducing the occurrence of re-growth oxide.

In addition, the substrate processing method according to the present disclosure uses a carbon-rich compound, thereby reducing the amount of by-products produced as compared with the use of a compound having a low carbon content in the processing process.

Table 1 shows the etch depths (nm) of the silicon nitride layers of the upper, middle, and lower portions of the ONO stack after the substrate treatment according to Comparative Example 1 and Present Examples 1 to 4.

Each of the upper, middle, and lower portions of the ONO stack includes 40 layers of combinations, each combination being composed of silicon oxide layer+silicon nitride layer. The etch depth nm of the silicon nitride layer was measured at three points of each of the upper, middle, and lower portions of the ONO stack and was expressed as an average value.

### Comparative Example 1

After placing the substrate having the ONO stack formed thereon in the reaction chamber, about 500 sccm of CF₄ gas and 50 sccm of CH₂F₂ were supplied thereto to perform etching for 60 seconds with 2000 W of RF power and a process pressure of about 1 Torr.

### Present Example 1

After placing the substrate having the ONO stack formed thereon in the reaction chamber, about 200 sccm of C₄F₆ gas was supplied thereto to perform plasma deposition for 2 minutes at a RF power of 1500 W, and a process pressure of about 1 Torr. Then, CF₄ 500 sccm and CH₂F₂ 50 sccm was supplied thereto to perform etching at a RF power of 2000 W, and a process pressure of about 1 Torr for 45 seconds.

### Present Example 2

The substrate was treated under the same conditions as in Present Example 1 except that the etching time was 60 seconds.

### Present Example 3

The substrate was treated under the same conditions as in Present Example 1 except that the etching time was 75 seconds.

### Present Example 4

The substrate was treated under the same conditions as in Present Example 1 except that the etching time was 90 seconds.

TABLE 1

| | Examples | | | | |
|---|---|---|---|---|---|
| | Comparative | Present | Present | Present | Present |
| | Example 1 | Example 1 | Example 2 | Example 3 | Example 4 |
| Upper | 268 nm | 0 nm | 0 nm | 0 nm | 0 nm |
| Middle | 200 nm | 97 nm | 140 nm | 160 nm | 210 nm |
| Lower | 156 nm | 63 nm | 105 nm | 135 nm | 190 nm |

Referring to Table 1, it may be identified that in the case of Comparative Example 1, the etching of the silicon nitride layer constituting the upper portion of the ONO stack is actively performed. On the other hand, it may be identified that in the case of Present Examples 1 to 4, the etching of the silicon nitride of the lower portion of the ONO stack is actively performed.

As described above, when the etching is performed actively on the upper portion of the ONO stack, selective etching of the lower portion of the ONO stack may not be easily performed in the subsequent etching process, and damage to the silicon oxide layer of the ONO stack, and regrowth, and the like may be problematic.

However, when the etching is performed actively on the lower portion of the ONO stack in a state in which the etch stop film or the protective film has been formed on the upper portion of the ONO stack, selective etching of the upper portion of the ONO stack may be easily performed in a subsequent etching process, and problems such as damage to the silicon oxide layer of the ONO stack and regrowth may be suppressed as much as possible.

Table 2 shows the etching depths (nm) of the silicon nitride layers of the upper, middle, and lower portions of the ONO stack after the substrate treatment according to Comparative Examples 2 to 3 and Present Example 4 as described above.

Each of the upper, middle, and lower portions of the ONO stack includes 40 layers of combinations, each combination of silicon oxide layer+silicon nitride layer. The etch depth nm of the silicon nitride layer was measured at three points of each of the upper, middle, and lower portions of the ONO stack and was expressed as an average value.

### Comparative Example 2

After the substrate on which the ONO stack had been formed was placed in the reaction chamber, about 500 sccm of CF₄ gas and 50 sccm of CH₂F₂ were supplied thereto to perform first etching for 30 seconds at a RF power of 2000 W and a process pressure of about 1 Torr, Then, 2000 sccm of O₂ gas was supplied thereto for O₂ plasma generation to perform passivation of the silicon oxide layers of the ONO stack for 120 seconds at a RF power of 1500 W and a process pressure of about 1 Torr. Then, the second etching was performed thereon again for 30 seconds.

### Comparative Example 3

After placing the substrate having the ONO stack formed thereon into the reaction chamber, about 500 sccm of CF₄ gas, and 200 sccm of CH₂F₂ were supplied thereto to perform etching on the stack for 60 seconds at a RF power of 2000 W and a process pressure of about 1 Torr.

TABLE 2

| | Examples | | |
|---|---|---|---|
| | Comparative | Comparative | Present |
| | Example 2 | Example 3 | Example 4 |
| Upper | 267 nm | 80 nm | 0 nm |
| Middle | 235 nm | 50 nm | 210 nm |
| Lower | 200 nm | 0 nm | 194 nm |

Referring to Table 2, as a result of applying O₂ plasma to a period between the first dry-etching and the second dry-etching, the amount by which the lower portion of the stack had been etched also increased. In addition, as a result of microscopic observation, it was confirmed that in the case of Comparative Example 2, the oxide damage in the ONO stack was excessive, and a necking phenomenon also occurred.

In addition, referring to Table 2, it may be identified that in the case of Comparative Example 3, the silicon nitride etching stop occurred when CH₂F₂ was excessively applied. In addition, it may be identified that the etching of the lower portion of the ONO stack is first stopped, and thus it is difficult to adjust the etching profile.

However, referring to Present Example 4 of Table 2, while there is little etching of the upper portion of the ONO stack, etching is concentrated on the lower portion of the ONO stack. In this case, based on the microscopic observation result, the oxide damage in the ONO stack was reduced, and necking was also rarely identified.

Although the present disclosure has been described with reference to the accompanying drawings, the present disclosure is not limited by the embodiments disclosed herein and the drawings, and it is obvious that various modifications may be made by those skilled in the art within the scope of the technical idea of the present disclosure. In addition, although the effects based on the configuration of the present disclosure are not explicitly described and illustrated in the description of the embodiment of the present disclosure above, it is obvious that predictable effects from the configuration should also be recognized.

1. A method for processing a substrate having an ONO stack formed thereon, wherein the ONO stack includes a stack structure in which silicon oxide layers and silicon nitride layers are alternately stacked on top of each other, wherein a through-hole extends through the ONO stack such that side surfaces of the silicon oxide layers and the silicon nitride layers are exposed, the method comprising:
(a) supplying a first processing gas to the through-hole to expose the ONO stack to the first processing gas; and
(b) supplying a second processing gas to the through-hole to expose the ONO stack to the second processing gas to dry-etch the silicon nitride layers of the ONO stack,
wherein the first processing gas includes CₓF_{y}, wherein a x/y is 0.5 or greater.

2. The method for processing the substrate of claim 1, wherein in the (a), a carbon-containing film is formed on exposed side surfaces of the silicon oxide layers and the silicon nitrides of an upper portion of the ONO stack.

3. The method for processing the substrate of claim 1, wherein the first processing gas includes C₄F₆ or C₄F₈.

4. The method for processing the substrate of claim 1, wherein in the (a), the ONO stack is exposed to plasma into which the first processing gas has been converted.

5. The method for processing the substrate of claim 1, wherein the second processing gas includes a fluorine-containing gas except for nitrogen trifluoride (NF₃) and a hydrogen-containing gas.

6. The method for processing the substrate of claim 5, wherein an atomic ratio (F:H) of fluorine and hydrogen contained in the second processing gas is in a range of 15:1 to 35:1.

7. The method for processing the substrate of claim 5, wherein in the (b), the ONO stack is exposed to plasma into which the second processing gas has been converted.

8. The method for processing the substrate of claim 7, wherein high frequency power having an RF frequency of 15 MHz inclusive to 60 MHz exclusive is used for converting the second processing gas into the plasma.

9. A method for processing a substrate having an ONO stack formed thereon, wherein the ONO stack includes a stack structure in which silicon oxide layers and silicon nitride layers are alternately stacked on top of each other, wherein a through-hole extends through the ONO stack such that side surfaces of the silicon oxide layers and the silicon nitride layers are exposed, the method comprising:
(a) placing the substrate in a reaction chamber;
(b) supplying a first processing gas into the reaction chamber;
(c) purging an inside of the reaction chamber using a purge gas;
(d) supplying a second processing gas into the reaction chamber;
(e) purging the inside of the reaction chamber using a purge gas; and
(f) performing a unit cycle a plurality of times, wherein (b) to (e) constitute the unit cycle,
wherein the first processing gas includes CₓF_{y}, wherein a x/y is 0.5 or greater,
wherein the second processing gas is an etching gas.

10. The method for processing the substrate of claim 9, wherein in the (b), a carbon-containing film is formed on exposed side surfaces of the silicon oxide layers and the silicon nitrides of an upper portion of the ONO stack.

11. The method for processing the substrate of claim 9, wherein the first processing gas includes C₄F₆ or C₄F₈.

12. The method for processing the substrate of claim 9, wherein in the (b), RF power is applied to the reaction chamber for converting the first processing gas into plasma.

13. The method for processing the substrate of claim 9, wherein the second processing gas includes a fluorine-containing gas except for nitrogen trifluoride (NF₃) and a hydrogen-containing gas.

14. The method for processing the substrate of claim 13, wherein an atomic ratio (F:H) of fluorine and hydrogen contained in the second processing gas is in a range of 15:1 to 35:1.

15. The method for processing the substrate of claim 13, wherein in the (d), RF power is applied to the reaction chamber for converting the second processing gas into plasma.

16. The method for processing the substrate of claim 15, wherein the RF power has a RF frequency of 15 MHz inclusive to 60 MHz exclusive.

17. The method for processing the substrate of claim 9, wherein the substrate processing method further comprises (g) supplying a third processing gas into the reaction chamber to further etch the silicon nitride layers of the ONO stack.

18. The method for processing the substrate of claim 17, wherein a type of the third processing gas is identical with a type of the second processing gas.
